(19) United States
(12) Patent Application Publication
(10) Pub. No.: US 2025/0351692 A1
(43) Pub. Date: Nov. 13, 2025

(54) DISPLAY DEVICE

(71) Applicant: Samsung Display Co., LTD., Yongin-si (KR)

(72) Inventors: Kye Uk LEE, Yongin-si (KR); Soo Hong CHEON, Yongin-si (KR)

(73) Assignee: Samsung Display Co., LTD., Yongin-si (KR)

(21) Appl. No.: 19/022,377

(22) Filed: Jan. 15, 2025

(30) Foreign Application Priority Data
May 7, 2024 (KR) 10-2024-0059891

(51) Int. Cl. H10K 59/131; H10K 59/126; H10K 102/00

(52) U.S. Cl. CPC H10K 59/131; H10K 59/126; H10K 2102/341

(57) ABSTRACT

The disclosure relates to a display device and an electronic device that can prevent a short circuit between a light-shielding layer and a connection electrode. According to an aspect of the disclosure, a display device includes: a substrate; a light-shielding layer disposed on the substrate; an active layer disposed on the light-shielding layer; a first transistor including a gate electrode disposed adjacent to the active layer; a light-emitting element electrically connected to the first transistor; and a connection electrode disposed on the active layer and the gate electrode, wherein: the connection electrode is connected to the active layer through a first contact hole in an interlayer insulating film and to the gate electrode through a second contact hole in the interlayer insulating film; and the light-shielding layer does not overlap the first contact hole.

### CROSS REFERENCE TO RELATED APPLICATION(S)

This application claims priority to and the benefits of Korean Patent Application No. 10-2024-0059891 under 35 U.S.C. § 119, filed on May 7, 2024 in the Korean Intellectual Property Office, the contents of which are hereby incorporated by reference in its entirety.

### BACKGROUND

### 1. Technical Field

The disclosure relates to a display device, and to a display device and an electronic device that can prevent a short circuit between a light-shielding layer and a connection electrode.

### 2. Description of the Related Art

An organic light emitting diode (OLED) display has a self-emitting characteristic and, unlike a liquid crystal display (LCD), does not require a separate light source, allowing for reduced thickness and weight. The OLED display exhibits high-quality characteristics such as low power consumption, high brightness, and high response speed and thus has been recognized as a next-generation display device for televisions, monitors, and portable electronic devices.

### SUMMARY

Aspects of the disclosure provide a display device that can prevent a short circuit between a light-shielding layer and a connection electrode.

However, aspects of the disclosure are not restricted to those set forth herein. The above and other aspects of the disclosure will become more apparent to one of ordinary skill in the art to which the disclosure pertains by referencing the detailed description of the disclosure given below.

According to an aspect of the disclosure, a display device may include a substrate; a light-shielding layer disposed on the substrate; an active layer disposed on the light-shielding layer; a first transistor including a gate electrode disposed adjacent to the active layer; a light-emitting element electrically connected to the first transistor; and a connection electrode disposed on the active layer and the gate electrode, wherein the connection electrode may be connected to the active layer through a first contact hole in an interlayer insulating film and to the gate electrode through a second contact hole in the interlayer insulating film; and the light-shielding layer may not overlap the first contact hole.

The light-shielding layer may have a hole that penetrates the light-shielding layer, and the hole of the light-shielding layer may overlap the first contact hole.

In a plan view, the hole of the light-shielding layer may surround the first contact hole.

The hole of the light-shielding layer may overlap the active layer.

The hole of the light-shielding layer may be disposed close to edges of the light-shielding layer.

The connection electrode in the first contact hole may penetrate the active layer.

The connection electrode may contact an inner wall of the penetrated active layer.

The connection electrode in the first contact hole may be surrounded by the hole of the light-shielding layer.

A side of the hole in the light-shielding layer may be open.

The display device may further include a second transistor and a third transistor electrically connected to the gate electrode of the first transistor.

The hole of the light-shielding layer may be disposed close to edges of the light-shielding layer, and in a plan view, the edges of the light-shielding layer may include a first edge facing a gate electrode of the second transistor and a second edge facing a gate electrode of the third transistor.

According to another aspect of the disclosure, a display device includes: a substrate; a light-shielding layer disposed on the substrate; an active layer disposed on the light-shielding layer; a first transistor including a gate electrode disposed adjacent to the active layer; a light-emitting element electrically connected to the first transistor; and a connection electrode disposed on the active layer and the gate electrode, wherein the connection electrode may be connected to the active layer through a first contact hole in an interlayer insulating film and to the gate electrode through a second contact hole in the interlayer insulating film, and the light-shielding layer may have a hole that overlaps the first contact hole.

According to an aspect of the disclosure, an electronic device comprising a display device, wherein the display device may include a substrate; a light-shielding layer disposed on the substrate; an active layer disposed on the light-shielding layer; a first transistor including a gate electrode disposed adjacent to the active layer; a light-emitting element electrically connected to the first transistor; and a connection electrode disposed on the active layer and the gate electrode, the connection electrode may be connected to the active layer through a first contact hole in an interlayer insulating film and to the gate electrode through a second contact hole in the interlayer insulating film; and the light-shielding layer may not overlap the first contact hole.

According to the aforementioned and other embodiments of the disclosure, a short circuit between a light-shielding layer and a connection electrode can be prevented.

It should be noted that the effects of the disclosure may not be limited to those described above, and other effects of the disclosure will be apparent from the following description.

### BRIEF DESCRIPTION OF THE DRAWINGS

The above and other aspects and features of the disclosure will become more apparent by describing in detail embodiments thereof with reference to the attached drawings, in which:

FIG. 1 is a schematic plan view illustrating a display device according to an embodiment of the disclosure;

FIG. 2 is a schematic plan view illustrating a display panel of FIG. 1;

FIG. 3 is a schematic circuit diagram illustrating a pixel according to an embodiment of the disclosure;

FIG. 4 is a schematic diagram illustrating the array of a display device according to another embodiment of the disclosure;

FIG. 5 is a schematic diagram selectively illustrating only a second light-shielding layer of FIG. 4;

FIG. 6 is a schematic cross-sectional view taken along the line X-X′ of FIG. 4;

FIG. 7 is a schematic diagram for explaining the principle of preventing a short circuit between the second light-shielding layer and a first connection electrode in the display device of FIG. 4;

FIG. 8 is a schematic diagram illustrating the array of a display device according to another embodiment of the disclosure; and

FIG. 9 is a schematic diagram selectively illustrating only a second light-shielding layer of FIG. 8.

FIG. 10 is a schematic block diagram of an electronic device according to an embodiment.

FIGS. 11, 12 and 13 are schematic diagrams of electronic devices according to various embodiments.

### DETAILED DESCRIPTION OF THE EMBODIMENTS

In the following description, for the purposes of explanation, numerous specific details are set forth in order to provide a thorough understanding of various embodiments or implementations of the disclosure. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in an embodiment.

Unless otherwise specified, the illustrated embodiments are to be understood as providing features of the disclosure. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the disclosure.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals and/or reference characters denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may represent different directions that are not perpendicular to one another. For the purposes of this disclosure, “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Throughout the specification, when an element is referred to as being “connected” to another element, the element may be “directly connected” to another element, or “electrically connected” to another element with one or more intervening elements interposed therebetween. Also, when an element is referred to as being “in contact” or “contacted” or the like to another element, the element may be in “electrical contact” or in “physical contact” with another element; or in “indirect contact” or in “direct contact” with another element.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein interpreted accordingly.

It will be understood that when an element such as a layer, film, region, or substrate is referred to as being “on” or “over” another element, it can be directly on the other element or intervening element(s) may also be present. In contrast, when an element is referred.

The term overlap may include layer, stack, face or facing, extending over, covering or partly covering or any other suitable term as would be appreciated and understood by those of ordinary skill in the art.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As used herein, a phrase “an element A on an element B” refers to that the element A may be disposed directly on the element B and/or the element A may be disposed indirectly on the element B via another element C. Like reference numerals denote like elements throughout the descriptions. The figures, dimensions, ratios, angles, numbers of elements given in the drawings are merely illustrative and are not limiting.

Features of various embodiments of the disclosure may be combined partially or totally. As will be clearly appreciated by those skilled in the art, technically various interactions and operations are possible. Various embodiments can be practiced individually or in combination.

Hereinafter, embodiments of the disclosure will be described with reference to the accompanying drawings.

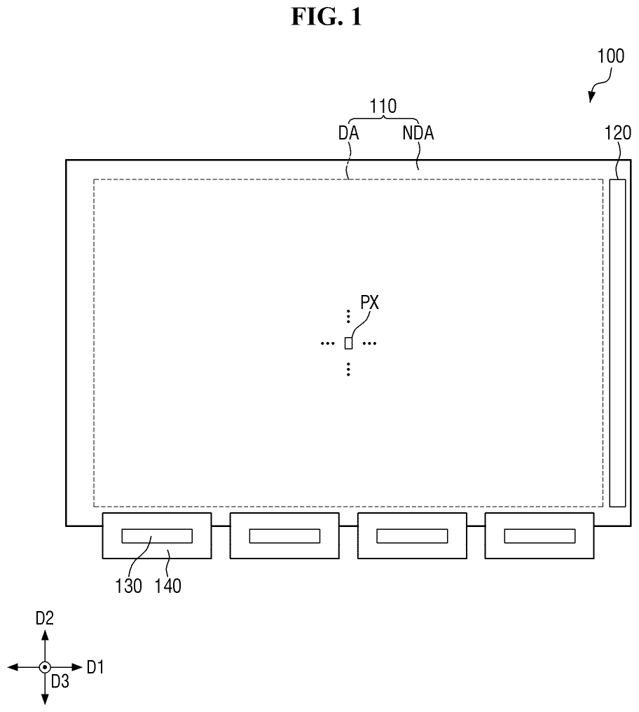

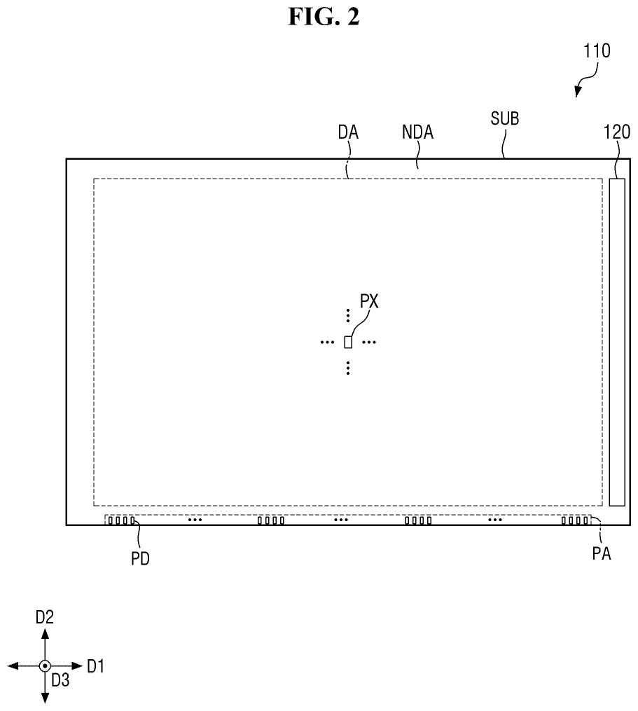

FIG. 1 is a schematic plan view illustrating a display device 100 according to an embodiment of the disclosure. FIG. 2 is a schematic plan view illustrating a display panel 110 of FIG. 1.

Referring to FIGS. 1 and 2, the display device 100, which is a device for displaying videos or still images, may be used as the display screen of various products such as mobile phones, smart phones, tablet personal computers (PCs), smart watches, watch phones, mobile communication terminals, electronic notebooks, e-book readers, portable multimedia players (PMPs), navigation devices, ultra-mobile PCs (UMPCs), as well as televisions (TVs), laptops, monitors, billboards, and Internet of Things (IoT) devices. These are presented as examples, and the display device 100 may also be employed in other electronic devices.

In an embodiment, the display device 100 may be a light-emitting display device such as an organic light-emitting display device including organic light-emitting diodes (OLEDs), a quantum dot light-emitting display device including a quantum dot light-emitting layer, an inorganic light-emitting display device including an inorganic semiconductor, or an ultra-small light-emitting display device including ultra-small light-emitting diodes (LEDs) such as micro-or nano-LEDs, but the disclosure is not limited thereto. In another example, the display device 100 may be another type of display device other than a light-emitting display device. Embodiments where the display device 100 is a light-emitting display device (e.g., an organic light-emitting display device) will hereinafter be disclosed.

The display device 100 may include a display panel 110, which may include pixels PX, and first and second driving units 120 and 130, which supply driving signals to the pixels PX. The display device 100 may include additional features. For example, the display device 100 may further include a power supply unit for supplying power supply voltages to the pixels PX, the first driving unit 120, the second driving unit 130, and a timing controller for controlling the operation of the first and second driving units 120 and 130.

The display panel 110 may include a display area DA and a non-display area NDA. The display area DA may be an area that displays an image by including the pixels PX. For example, the display area DA may include pixels where the respective pixels PX are disposed. The non-display area NDA may be the remaining area in the display panel 110 excluding the display area DA, and no image may be displayed in the non-display area NDA. In an embodiment, the non-display area NDA may be located around the display area DA and may surround the display area DA.

FIGS. 1 and 2 define a first direction D1, a second direction D2, and a third direction D3. In an embodiment, the first direction D1 may be the horizontal direction of the display panel 110, the second direction D2 may be the vertical direction of the display panel 110, and the third direction D3 may be the thickness direction of the display panel 110.

In an embodiment, the display panel 110 may be rectangular in shape on a plane. FIGS. 1 and 2 illustrate a display panel 110 with a longer horizontal length than its vertical length, but the shape of the display panel 110 is not particularly limited. For example, the display panel 110 may have a longer vertical length than its horizontal length, or it may be square-shaped. The display panel 110 may include angular corners or rounded corners.

The planar shape of the display panel 110 is not limited to the illustrated rectangular shape and may be applied in various other shapes. For example, the display panel 110 may have another polygonal shape that is a non-rectangular, a circular shape, an elliptical shape, or an irregular shape.

In an embodiment, the display panel 110 may be substantially flat on a plane defined by the first and second directions DI and D2 and may have a uniform thickness in the third direction D3. In another example, the display panel 110 may be provided in a three-dimensional (3D) shape having curved surfaces.

The display panel 110 may be provided as a rigid panel that is substantially non-deformable or may be provided as a flexible panel that can be deformed in at least one part, such as being foldable, bendable, or rollable. The display panel 110 may be provided in the display device 100 in a non-bent state or in a bent state in some sections.

The display panel 110 may include a substrate SUB and pixels PX disposed on the substrate SUB. The pixels PX may be arranged in the display area DA on the substrate SUB.

The substrate SUB, which is a base member for manufacturing or providing the display panel 110, may form the base surface of the display panel 110. The substrate SUB may include the display area DA and the non-display area NDA around the display area DA.

The display area DA may have various shapes. For example, the display area DA may have a rectangular shape, a non-rectangular polygonal shape, a circular shape, an elliptical shape, an irregular shape, or another shape. In an embodiment, the display area DA may have a shape corresponding to the shape of the display panel 110.

In the display area DA, the pixels PX may be provided or arranged. For example, the display area DA may include pixel regions where the individual pixels PX are arranged.

In an embodiment, the display device 100 may be a light-emitting display device, and each of the pixels PX may include a light-emitting element located in each emission area and a pixel circuit connected to the light-emitting element. The term “connected,” as used herein, may encompass both electrical and/or physical connections. Each pixel circuit may include transistors (e.g., transistors including at least one switching transistor and a driving transistor generating a driving current corresponding to a data signal) and at least one capacitor (e.g., a storage capacitor).

The non-display area NDA may include a pad area PA where pads PD are disposed. In an embodiment, the non-display area NDA may further include a driving circuit area located on at least one side of the display area DA. In the non-display area NDA, at least one driving unit, the pads PD, and/or wiring may be disposed.

In the driving circuit area, at least one driving unit or a part of the driving unit for driving the pixels PX may be disposed. For example, in the driving circuit area on the substrate SUB, circuit elements constituting the first driving unit 120 (e.g., driving transistors and driving capacitors constituting the stage circuits of the first driving unit 120) may be disposed. In an embodiment, the circuit elements of the first driving unit 120 may be formed in the display panel 110 along with the pixels PX. In an embodiment, the driving transistors provided in the first driving unit 120 may be of substantially the same type and/or structure as (or a similar type and/or structure to) the transistors provided in the pixels PX, and may be formed simultaneously with the transistors of the pixels PX.

The pads PD may be arranged in the pad area PA. At least one circuit board 140 may be arranged and/or bonded on the pad area PA. In an embodiment, circuit boards 140 connected to different pads PD may be disposed in the pad area PA. The pads PD may include signal pads and power pads for transmitting to the inside of the display panel 110 driving signals and power supply voltages for driving the pixels PX and/or the first driving unit 120.

The first and second driving units 120 and 130 may generate driving signals for controlling the operation timing and brightness of the pixels PX and may supply the driving signals to the pixels PX. For example, the first driving unit 120 may be a gate driving unit including a scan driver and may be connected to the pixels PX through respective gate lines. The first driving unit 120 may supply gate signals (e.g., scan signals and/or control signals for controlling the driving timing of the pixels PX, including emission control signals) to the pixels PX. The second driving unit 130 may be a data driving unit including source driving circuits and may be connected to the pixels PX through respective data lines. The second driving unit 130 may supply data signals to the pixels PX.

In an embodiment, at least one of the first and second driving units 120 and 130 or parts of the first and second driving units 120 and 130 may be embedded in the display panel 110. For example, the first driving unit 120 or a part of the first driving unit 120 may be disposed on the substrate SUB of the display panel 110 and may be disposed and/or formed in the non-display area NDA.

In FIG. 1, the first driving unit 120 may be illustrated as being formed on one side of the display area DA (e.g., in a part of the non-display area NDA on the right side of the display area DA), but the disclosure is not limited thereto. One of the first and second driving units 120 and 130, for example, the first driving unit 120, may be located on another side of the display area DA (e.g., in a part of the non-display area NDA on the left side of the display area DA), or may be located on both sides of the display area DA (e.g., in parts of the non-display area NDA on both the left and right sides of the display area DA). In another example, a part of the first driving unit 120 may be located in the non-display area NDA, and another part of the first driving unit 120 may be located in a non-emission area within the display area DA (e.g., the area between the emission areas of the pixels PX).

In an embodiment, the other driving unit, or a part thereof, may be disposed or formed outside the display panel 110 and electrically connected to the display panel 110. For example, the second driving unit 130 may be implemented with integrated circuit (IC) chips and disposed on circuit boards 140 electrically connected to the pixels PX of the display panel 110. The second driving unit 130 may be implemented as at least one IC chip and mounted in the non-display area NDA of the display panel 110.

The circuit boards 140 may be connected to the display panel 110 through the pads PD. In an embodiment, the circuit boards 140 may be flexible films such as flexible printed circuit boards (FPCBs), printed circuit boards (PCBs), or chip-on-films (COFs), but the disclosure is not limited thereto. In an embodiment, the circuit boards 140 may be connected to the timing controller and/or the power supply unit through circuit boards, connectors, etc.

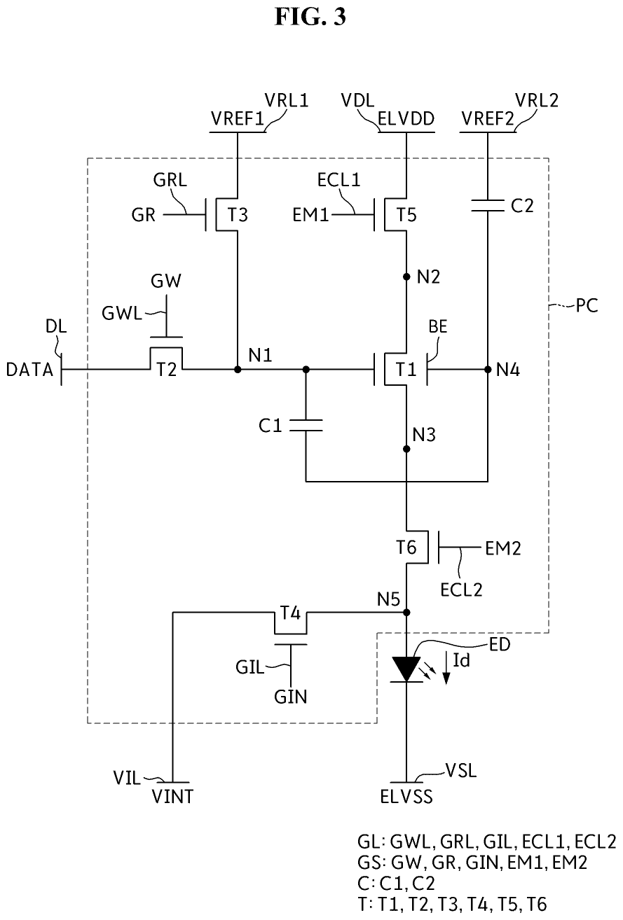

FIG. 3 is a schematic circuit diagram illustrating a pixel PX according to an embodiment of the disclosure. For example, FIG. 3 illustrates a pixel PX of the display device 100 that includes a light-emitting element ED. However, the type and/or structure of the pixel PX included in the display device 100 is not particularly limited and may vary.

Referring to FIGS. 1, 2, and 3, a pixel PX may include a light-emitting element ED and a pixel circuit PC connected to the light-emitting element ED. The light-emitting element ED, which is the light source of the pixel PX, may be an OLED, but the disclosure is not limited thereto. The pixel circuit PC may control the emission timing and brightness of the light-emitting element ED.

The pixel circuit PC may include transistors T and at least one capacitor C. For example, the pixel circuit PC may include first through fifth transistors T1 through T5, a first capacitor C1, and a second capacitor C2. FIG. 3 depicts an embodiment where all the first through sixth transistors T1 through T6 are N-type transistors, but the types of the transistors T are not limited thereto. For example, at least one of the transistors T may be formed as a P-type transistor.

The pixel circuit PC may supply a driving current Id to the light-emitting element ED in response to driving signals supplied from the first and second driving units 120 and 130. For example, the pixel circuit PC may supply the driving current Id to the light-emitting element ED in response to each gate signal GS supplied from the first driving unit 120 through a corresponding gate line GL and each data signal DATA supplied from the second driving unit 130 through a corresponding data line DL.

The first transistor T1 may be the driving transistor of the pixel PX, where the magnitude of a drain-source current (e.g., the driving current Id) is determined by a gate-source voltage. The second through sixth transistors T2 through T6 may be switching transistors that turn on or off according to their respective gate-source voltages. Depending on the type (e.g., P-type or N-type) and/or operating conditions of each of the first through sixth transistors T1 through T6, the first electrode of each of the first through sixth transistors T1 through T6 may be a drain electrode (or drain region) or a source electrode (or source region), while the second electrode of each of the first through sixth transistors T1 through T6 may be a different type of electrode from the first electrode of each of the first through sixth transistors T1 through T6. For example, if the first electrode of each of the first through sixth transistors T1 through T6 is a drain electrode, the second electrode of each of the first through sixth transistors T1 through T6 may be a source electrode.

The pixel PX may be connected to a first gate line GWL that transmits a first gate signal GW (e.g., a scan signal), a second gate line GIL that transmits a second gate signal GIN, a third gate line GRL that transmits a third gate signal GR, first and second emission control lines ECL1 and ECL2 that transmit first and second emission control signals EM1 and EM2, and a data line DL that transmits a data signal DATA. The pixel PX may be connected to a first driving power line VDL that transmits a first pixel voltage ELVDD (also referred to as “first pixel power voltage”) and a second driving power line VSL that transmits a second pixel voltage ELVSS (also referred to as “second pixel power voltage”). In an embodiment, the pixel PX may be further connected to an initialization power line VIL that transmits an initialization voltage VINT (also referred to as “third pixel power voltage”), a first reference power line VRL1 that transmits a first reference voltage VREF1 (also referred to as “fourth pixel power voltage”), and a second reference power line VRL2 that transmits a second reference voltage VREF2 (also referred to as “fifth pixel power voltage”).

In an embodiment, the first through sixth transistors T1 through T6 may be oxide transistors, which include an oxide semiconductor (e.g., oxide semiconductor material). and may also be referred to as “oxide semiconductor transistors.” For example, the active layer of each of the first through sixth transistors T1 through T6 may include an oxide semiconductor, but the disclosure is not limited thereto. For example, at least one of the transistors T may be formed of a semiconductor material other than an oxide semiconductor (e.g., amorphous silicon or polysilicon).

Since the oxide semiconductor has high carrier mobility and low leakage current, significant voltage drops may not occur even in case that the driving time of an oxide transistor is extended. For example, in a case where the pixel PX may include an oxide transistor, changes in the brightness and/or color of an image that may be caused by voltage drops may be minimal even in case that driven at low frequency, allowing for low-frequency driving. In case that the first through sixth transistors T1 through T6 are formed as oxide transistors, they can reduce or prevent leakage current in the pixel PX and reduce power consumption.

The oxide semiconductor may be sensitive to light, and external light may cause variations in the amount of current. In an embodiment, a light-shielding pattern or a light-shielding electrode (e.g., a bottom electrode or a back-gate electrode) may be disposed below the active layer included in at least one of the transistors T to block external light. This can stabilize the operating characteristics of the at least one of the transistors T.

The first transistor T1 may include a gate electrode connected to a first node N1, a first electrode (e.g., first drain electrode) connected to a second node N2, and a second electrode (e.g., first source electrode) connected to a third node N3. The first electrode of the first transistor T1 may be connected to the first driving power line VDL via the fifth transistor T5, and the second electrode of the first transistor T1 may be connected to the light-emitting element ED via the sixth transistor T6. The first transistor T1 may control the magnitude (e.g., intensity) of the driving current Id flowing to the light-emitting element ED in response to the data signal DATA transmitted to the first node N1.

In an embodiment, the first transistor T1 may further include a bottom electrode BE (e.g., a bottom-gate electrode or back-gate electrode of the first transistor T1) connected to a fourth node N4. By connecting the bottom electrode BE of the first transistor T1 to the fourth node N4, the first transistor T1 may be formed as a double-gate transistor (e.g., a source-sync double-gate transistor), improving its operational characteristics.

The second transistor T2 may include a second gate electrode connected to the first gate line GWL, a first electrode (e.g., second drain electrode) connected to the data line DL, and a second electrode (e.g., second source electrode) connected to the first node N1. The second transistor T2 may be turned on by the first gate signal GW (e.g., a gate-on voltage of the first gate signal GW) transmitted via the first gate line GWL, connecting the data line DL to the first node N1. Thus, the data signal DATA transmitted via the data line DL may be delivered to the first node N1.

The third transistor T3 may include a gate electrode connected to the third gate line GRL, a first electrode (e.g., third source electrode) connected to the first reference power supply line VRL1, and a second electrode (e.g., third drain electrode) connected to the first node N1. The third transistor T3 may be turned on by the third gate signal GR transmitted via the third gate line GRL, delivering the first reference voltage VREF1 transmitted via the first reference power supply line VRL1 to the first node N1.

The fourth transistor T4 may include a gate electrode connected to the second gate line GIL, a first electrode (e.g., fourth drain electrode) connected to the fifth node N5, and a second electrode (e.g., fourth source electrode) connected to the initialization power supply line VIL. The fourth transistor T4 may be turned on by the second gate signal GIN transmitted via the second gate line GIL, delivering the initialization voltage VINT transmitted via the initialization power supply line VIL, to the fifth node N5.

The fifth transistor T5 may include a gate electrode connected to a first emission control line ECL1, a first electrode (e.g., fifth drain electrode) connected to the first driving power supply line VDL, and a second electrode (e.g., fifth source electrode) connected to the second node N2 (or the first electrode of the first transistor T1). The fifth transistor T5 may be turned on by a first emission control signal EM1 (e.g., a gate-on voltage of the first emission control signal EM1) transmitted via the first emission control line ECL1, thereby controlling the emission timing of the pixel PX.

The sixth transistor T6 may include a gate electrode connected to a second emission control line ECL2, a first electrode (e.g., sixth drain electrode) connected to the third node N3 (or the second electrode of the first transistor T1), and a second electrode (e.g., fifth source electrode) connected to the fifth node N5. The sixth transistor T6 may be turned on by a second emission control signal EM2 (e.g., a gate-on voltage of the second emission control signal EM2) transmitted via the second emission control line ECL2, thereby controlling the emission timing of the pixel PX.

The second through sixth transistors T2 through T6 may or may not include bottom electrodes. In an embodiment, at least one switching transistor among the second through sixth transistors T2 through T6 may include a bottom electrode, which may be connected to the gate electrode of the at least one switching transistor. Connecting the bottom electrode to the gate electrode of a switching transistor can improve the off characteristics and switching speed of the switching transistor, provide additional voltage tolerance, reduce leakage current, and enhance voltage stability. For example, by forming a switching transistor with a short channel oxide transistor in a double-gate structure such as a gate-sync structure, the operational characteristics of the switching transistor can be improved.

The first capacitor C1 may be connected between the first node N1 and the fourth node N4. As a storage capacitor of the pixel PX, the first capacitor C1 may store a voltage corresponding to the threshold voltage of the first transistor T1 and the data signal DATA (e.g., data voltage).

The second capacitor C2 may be connected between the second reference power supply line VRL2 and the fourth node N4 (e.g., the bottom electrode BE of the first transistor T1). In an embodiment, the capacitance of the second capacitor C2 may be smaller than that of the first capacitor C1.

The light-emitting element ED may be connected between the fifth node N5 and the second driving power supply line VSL. For example, the light-emitting element ED may include a first electrode (e.g., anode electrode or pixel electrode) connected to the third node N3, a second electrode (e.g., cathode electrode or common electrode) facing the first electrode and connected to the second driving power supply line VSL, and a light-emitting layer disposed between the first and second electrodes. In an embodiment, the first electrode of the light-emitting element ED may be an individual electrode provided for each pixel PX, and the second electrode of the light-emitting element ED may be a common electrode shared by a pixels PX. The light-emitting element ED may emit light with a brightness corresponding to the driving current Id supplied from the pixel circuit PC during the period of supply of the driving current Id.

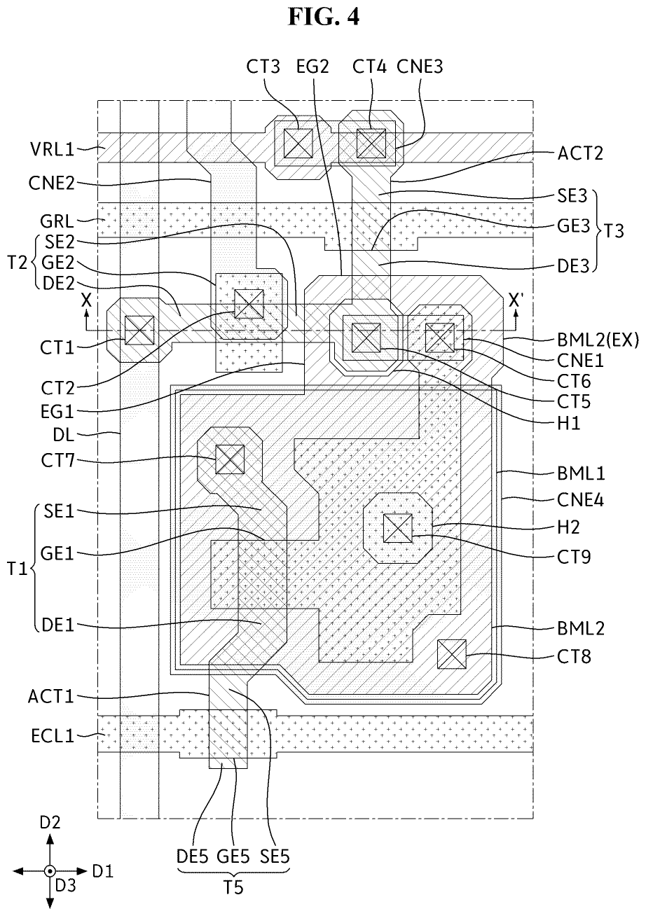

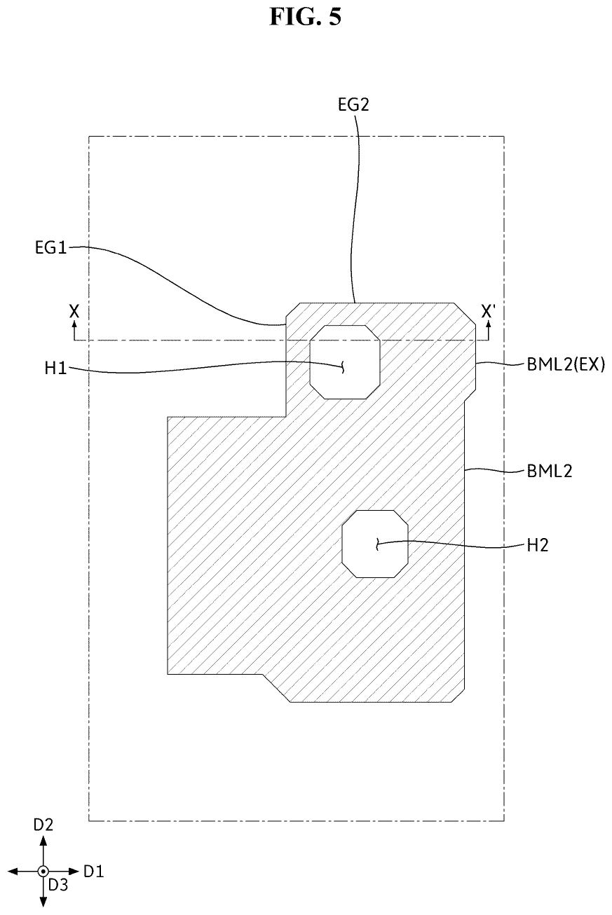

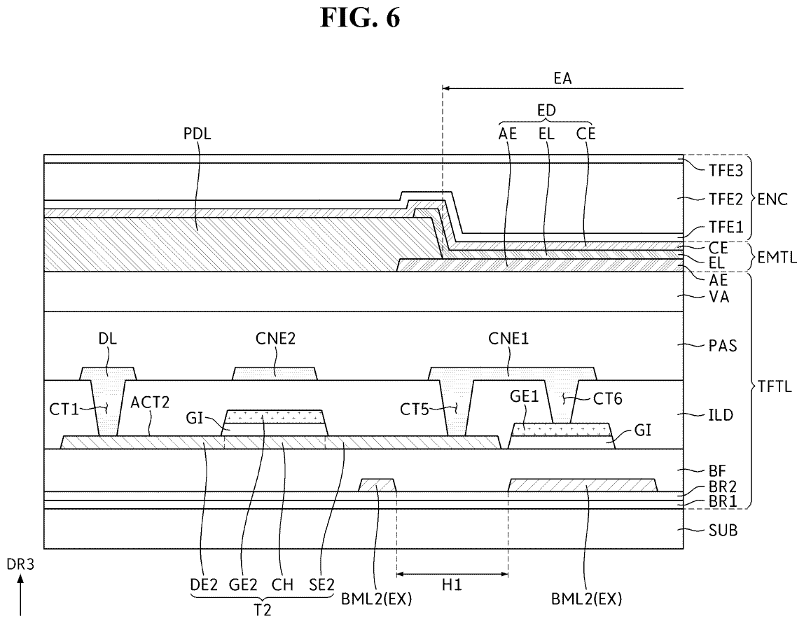

FIG. 4 is a schematic diagram illustrating an array of a display device 100 according to another embodiment of the disclosure, FIG. 5 is a schematic diagram selectively illustrating only a second light-shielding layer BML2 of FIG. 4, and FIG. 6 is a schematic cross-sectional view taken along the line X-X′ of FIG. 4. FIG. 4 illustrates, for example, an array for the pixel of FIG. 3.

Referring to FIG. 6, the display device 100 may include a substrate SUB, a thin-film transistor layer TFTL, a light-emitting element layer EMTL, and an encapsulation layer ENC. The thin-film transistor layer TFTL, the light-emitting element layer EMTL, and the encapsulation layer ENC may be sequentially arranged or disposed along the third direction D3 on the substrate SUB. The thin-film transistor layer TFTL may include the first through sixth transistors T1 through T6, the first capacitor C1, and the second capacitor C2 of FIG. 3.

The substrate SUB may be a rigid substrate or a flexible substrate that is bendable, foldable, or rollable. The substrate SUB may be formed of an insulating material such as glass, quartz, or polymer resin. Examples of the polymer resin include polyethersulfone (PES), polyacrylate (PA), polyarylate (PAR), polyetherimide (PEI), polyethylene naphthalate (PEN), polyethylene terephthalate (PET), polyphenylene sulfide (PPS), polyallylate, polyimide (PI), polycarbonate (PC), cellulose triacetate (CAT), cellulose acetate propionate (CAP), and a combination thereof. In another example, the substrate SUB may include a metallic material.

A first barrier layer BR1 may be disposed on the substrate SUB. For example, the first barrier layer BR1 may be disposed on the entire surface of the substrate SUB. The first barrier layer BR1 may protect the first through sixth transistors T1 through T6 of the thin-film transistor layer TFTL and a light-emitting layer EL of the light-emitting element layer EMTL from moisture penetrating through the substrate SUB, which is vulnerable to moisture. The first barrier layer BR1 may consist of inorganic films that are alternately stacked. For example, the first barrier layer BR1 may be formed as a multilayer film in which one or more inorganic films among a silicon nitride layer, a silicon oxynitride layer, a silicon oxide layer, a titanium oxide layer, and an aluminum oxide layer are alternately stacked.

Referring to FIG. 4, a first light-shielding layer BML1 may be disposed on the first barrier layer BR1. The first light-shielding layer BML1 may be formed of a metallic material such as chromium (Cr) or molybdenum (Mo), or of black ink or black dye.

A second barrier layer BR2 may be disposed on the first light-shielding layer BML1. The second barrier layer BR2 and the first barrier layer BR1 may include the same material and composition.

A second light-shielding layer BML2 and the first reference power supply line VRL1 may be disposed on the second barrier layer BR2. The second light-shielding layer BML2 may be disposed on the second barrier layer BR2 to overlap the first light-shielding layer BML1. As illustrated in FIGS. 4, 5, and 6, the second light-shielding layer BML2 may have a first hole H1 and a second hole H2. The first hole H1 and the second hole H2 may penetrate the second light-shielding layer BML2 in the third direction D3. In an embodiment, the second light-shielding layer BML2 may have the first hole H1 in an area corresponding to a fifth contact hole CT5 (e.g., a fifth contact hole CT5 that connects a first connection electrode CNE1 and a second active layer ACT2) so that the second light-shielding layer BML2 may not overlap the fifth contact hole CT5 in the third direction D3. The first hole H1 may be disposed in an extension portion EX of the second light-shielding layer BML. The extension portion EX of the second light-shielding layer BML may overlap the second active layer ACT2. For example, the upper edge of the extension portion EX may overlap the second active layer ACT2, and the left edge of the extension portion EX may overlap the second active layer ACT2. Accordingly, the parasitic capacitance between the third gate line GRL and the first node N1 can be minimized, and the parasitic capacitance between the first gate line GWL and the first node N1 can be minimized.

A buffer layer BF may be disposed on the second light-shielding layer BML2. The buffer layer BF may protect the first through sixth transistors T1 through T6 of the thin-film transistor layer TFTL and the light-emitting layer EL of the light-emitting element layer EMTL from moisture penetrating through the substrate SUB, which is vulnerable to moisture. The buffer layer BF may consist of inorganic films that are alternately stacked. For example, the buffer layer BF may be formed as a multilayer film in which one or more inorganic films among a silicon nitride layer, a silicon oxynitride layer, a silicon oxide layer, a titanium oxide layer, and an aluminum oxide layer are alternately stacked.

A first active layer ACTI and a second active layer ACT2 may be disposed on the buffer layer BF. For example, the first active layer ACT1 may be disposed on the buffer layer BF to overlap the second light-shielding layer BML2, and the second active layer ACT2 may be disposed on the buffer layer BF to overlap the second light-shielding layer BML2 and the first reference power supply line VRL1. The first active layer ACT1 may be an oxide-based active layer. For example, the first active layer ACT1 may be an oxide semiconductor including indium-gallium-zinc oxide (IGZO) or indium-gallium-zinc-tin oxide (IGZTO). The second active layer ACT2 and the first active layer ACT1 may include a same material. For example, the second active layer ACT2 may be an active layer of an oxide substrate.

A gate insulating film GI may be disposed on each of the first active layer ACT1, the second active layer ACT2, and the buffer layer BF. For example, the gate insulating film GI may be disposed on a channel region CH of the second active layer ACT2 to overlap the channel region CH. The gate insulating film GI may be disposed on the buffer layer BF to overlap the second light-shielding layer BML2. The gate insulating film GI may include at least one of tetraethyl orthosilicate (TEOS), silicon nitride (SiNₓ), and silicon dioxide (SiO₂). For example, the gate insulating film GI may have a dual-layer structure in which a silicon nitride film with a thickness of about 40 nm and a TEOS film with a thickness of about 80 nm are sequentially stacked.

A first gate electrode GE1 of the first transistor T1, the second gate electrode GE2 of the second transistor T2, a third gate electrode GE3 of the third transistor T3, a fourth gate electrode of the fourth transistor T4 (in, e.g., FIG. 3), a fifth gate electrode GE5 of the fifth transistor T5, and a sixth gate electrode of the sixth transistor T6 (in, e.g., FIG. 3) may be disposed on the gate insulating film GI. For example, the first gate electrode GE1 may be disposed on the gate insulating film GI to overlap the channel region of the first transistor T1, the second gate electrode GE2 may be disposed on the gate insulating film GI to overlap the channel region CH of the second transistor T2, the third gate electrode GE3 may be disposed on the gate insulating film GI to overlap the channel region of the third transistor T3, the fourth gate electrode may be disposed on the gate insulating film GI to overlap the channel region of the fourth transistor T4, the fifth gate electrode GE5 may be disposed on the gate insulating film GI to overlap the channel region of the fifth transistor T5, and the sixth gate electrode may be disposed on the gate insulating film GI to overlap the channel region of the sixth transistor T6. The first gate electrode GE1 may be connected to the first light-shielding layer BML1 through a ninth contact hole CT9 penetrating the gate insulating film GI and the second hole H2 of the second light-shielding layer BML2. A first drain electrode DE1 and a first source electrode SE1 may be formed or disposed on both sides of the first gate electrode GE1 of the first active layer ACT1, a second drain electrode DE2 and a second source electrode SE2 may be formed or disposed on both sides of the second gate electrode GE2 of the second active layer ACT2, a third drain electrode DE3 and a third source electrode SE3 may be formed or disposed on both sides of the third gate electrode GE3 of the second active layer ACT2, and a fifth drain electrode DE5 and a fifth source electrode SE5 may be formed or disposed on both sides of the fifth gate electrode GE5 of the first active layer ACT1.

In a plan view, the first hole HI of the second light-shielding layer BML2 may be disposed close to the edges of the second light-shielding layer BML2. For example, in a plan view, the second light-shielding layer BML2 may include a first edge EG1 facing the second gate electrode GE2 and a second edge EG2 facing the third gate electrode GE3, with the first hole H1 disposed close to the first and second edges EG1 and EG2.

An interlayer insulating film ILD may be disposed on the first gate electrode GE1, the second gate electrode GE2, the third gate electrode GE3, the fourth gate electrode, the fifth gate electrode GE5, and the sixth gate electrode. The interlayer insulating film ILD may include an inorganic film, such as a silicon nitride layer, a silicon oxynitride layer, a silicon oxide layer, a titanium oxide layer, or an aluminum oxide layer. In another example, interlayer insulating film ILD may include inorganic films.

A data line DL, the first connection electrode CNE1, a second connection electrode CNE2, a third connection electrode CNE3, and a fourth connection electrode CNE4 may be disposed on the interlayer insulating film ILD. The data line DL may be connected to the second drain electrode DE2 of the second transistor T2 through the first contact hole CT1 penetrating the interlayer insulating film ILD. One side of the first connection electrode CNE1 may be connected to the second source electrode SE2 of the second transistor T2 through the fifth contact hole CT5 penetrating the interlayer insulating film ILD, and the other side of the first connection electrode CNE1 may be connected to the first gate electrode GE1 through the sixth contact hole CT6 penetrating the interlayer insulating film ILD. One side of the second connection electrode CNE2 may be connected to the second gate electrode GE2 through the second contact hole CT2 penetrating the interlayer insulating film ILD, and the other side of the second connection electrode CNE2 may be connected to the first gate line GWL (in, e.g., FIG. 3) through a contact hole penetrating the interlayer insulating film ILD. One side of the third connection electrode CNE3 may be connected to the first reference power supply line VRL1 through the third contact hole CT3 penetrating the interlayer insulating film ILD and the buffer layer BF, and the other side of the third connection electrode CNE3 may be connected to the third source electrode SE3 of the third transistor T3 through the fourth contact hole CT4 penetrating the interlayer insulating film ILD. One side of the fourth connection electrode CNE4 may be connected to the first source electrode SE1 of the first transistor T1 through the seventh contact hole CT7 penetrating the interlayer insulating film ILD, and the other side of the fourth connection electrode CNE4 may be connected to the second light-shielding layer BML2 through the eighth contact hole CT8 penetrating the interlayer insulating film ILD and the buffer layer BF.

A passivation layer PAS may be disposed on the data line DL, the first connection electrode CNE1, the second connection electrode CNE2, the third connection electrode CNE3, and the fourth connection electrode CNE4. The passivation layer PAS may include an inorganic film.

A via layer VA may be formed on the passivation layer PAS. The via layer VA may include an organic film including a material such as an acrylic resin, epoxy resin, phenolic resin, polyamide resin, or polyimide resin.

The light-emitting element layer EMTL may be disposed on the via layer VA. The light-emitting element layer EMTL may include a pixel-defining film PDL and a light-emitting element ED stacked along the third direction D3. The light-emitting element ED may include an anode electrode AE, a light-emitting layer EL, and a cathode electrode CE.

The anode electrode AE of the light-emitting clement ED may be disposed on the via layer VA. The anode electrode AE may be connected to a sixth drain electrode of the sixth transistor T6 (in, e.g., FIG. 3) through a contact holes therebelow.

An emission area EA refers to the area where the anode electrode AE, the light-emitting layer EL, and the cathode electrode CE are sequentially stacked, and where holes from the anode electrode AE and electrons from the cathode electrode CE combine in the light-emitting layer EL to emit light.

In a top emission structure, where light is emitted in the direction of the cathode electrode CE relative to the light-emitting layer EL, the anode electrode AE may be formed as a single layer of Mo, titanium (Ti), copper (Cu), or aluminum (Al), or as a stacked structure to increase reflectivity, such as a titanium/aluminum/titanium (Ti/Al/Ti) structure, an aluminum/ITO/aluminum (ITO/Al/ITO) structure, a silver (Ag)-palladium (Pd)-copper (Cu) (APC) alloy, or an APC alloy/ITO structure (e.g., ITO/APC/ITO).

The pixel-defining film PDL may define the emission area EA of the pixel PX. To this end, the pixel-defining film PDL may be disposed on the via layer VA to expose a portion of the anode electrode AE. The pixel-defining film PDL may cover the edges of the anode electrode AE. The pixel-defining film PDL may be formed of an organic film such as an acrylic resin, epoxy resin, phenolic resin, polyamide resin, or polyimide resin.

The light-emitting layer EL may be disposed on the anode electrode AE. The light-emitting layer EL may include an organic material that can emit light of a predetermined or selectable color. For example, the light-emitting layer EL may include a hole transport layer, an organic material layer, and an electron transport layer. The organic material layer may include a host and a dopant. The organic material layer may include a material that emits light of a predetermined or selectable wavelength and may be formed using a phosphorescent material or a fluorescent material.

For example, the organic material layer of the light-emitting layer EL emitting light of a first color (e.g., blue) may include a host material containing carbazole biphenyl (CBP) or 1,3-bis(carbazol-9-yl) (mCP) and a phosphorescent dopant material containing (4,6-F2ppy)2Irpic or L2BD111, but the disclosure is not limited thereto.

The organic material layer of the light-emitting layer EL emitting light of a second color (e.g., green) may include a host material containing CBP or mCP and a phosphorescent dopant material containing fac tris(2-phenylpyridine)iridium (Ir(ppy)3). For example, the organic material layer of the light-emitting layer EL emitting light of the second color may be a fluorescent material containing tris(8-hydroxyquinolino)aluminum (Alq3), but the disclosure is not limited thereto.

The organic material layer of the light-emitting layer EL emitting light of a third color (e.g., red) may include a host material containing CBP or mCP and a phosphorescent dopant material containing bis(1-phenylisoquinoline) acetylacetonate iridium (PIQIr(acac)), bis(1-phenylquinoline)acetylacetonate iridium (PQIr(acac)), tris(1-phenylquinoline)iridium (PQIr), or octaethylporphyrin platinum (PtOEP), but the disclosure is not limited thereto. For example, the organic material layer of the light-emitting layer EL emitting light of the third color may be a fluorescent material containing PBD:Eu(DBM)3(Phen) or perylene, but the disclosure is not limited thereto.

The cathode electrode CE may be disposed on the light-emitting layer EL. The cathode electrode CE may be disposed to cover the light-emitting layer EL. The cathode electrode CE may be a common layer commonly disposed on a light-emitting layers EL. A capping layer may be formed on the cathode electrode CE.

In a top emission structure, the cathode electrode CE may be formed of a transparent conductive oxide (TCO) such as ITO or indium-zinc-oxide (IZO) that can transmit light, or a semi-transmissive conductive material such as magnesium (Mg), silver (Ag), or an alloy thereof. In case that the cathode electrode CE is formed of a semi-transmissive conductive material, the light output efficiency can be increased by micro cavities.

The encapsulation layer ENC may be formed on the light-emitting element layer EMTL. The encapsulation layer ENC may include at least one inorganic film to prevent oxygen or moisture from penetrating the light-emitting element layer EMTL. The encapsulation layer ENC may include at least one organic film to protect the light-emitting element layer EMTL from foreign substances such as dust. For example, the encapsulation layer ENC may include a first encapsulation inorganic film TFE1, an encapsulation organic film TFE2, and a second encapsulation inorganic film TFE3.

The first encapsulation inorganic film TFE1 may be disposed on the cathode electrode CE, the encapsulation organic film TFE2 may be disposed on the first encapsulation inorganic film TFE1, and the second encapsulation inorganic film TFE3 may be disposed on the encapsulation organic film TFE2. The first and second encapsulation inorganic films TFE1 and TFE3 may be formed as multilayer films in which one or more inorganic films among a silicon nitride film, a silicon oxynitride film, a silicon oxide film, a titanium oxide film, and an aluminum oxide film are alternately stacked. The encapsulation organic film TFE2 may be an organic film including a material such as an acrylic resin, epoxy resin, phenolic resin, polyamide resin, or polyimide resin.

In an embodiment, the first capacitor C1 (in, e.g., FIG. 3) may be formed in the region where the first light-shielding layer BML1, the second light-shielding layer BME2, the first gate electrode GE1, and the fourth connection electrode CNE4 overlap.

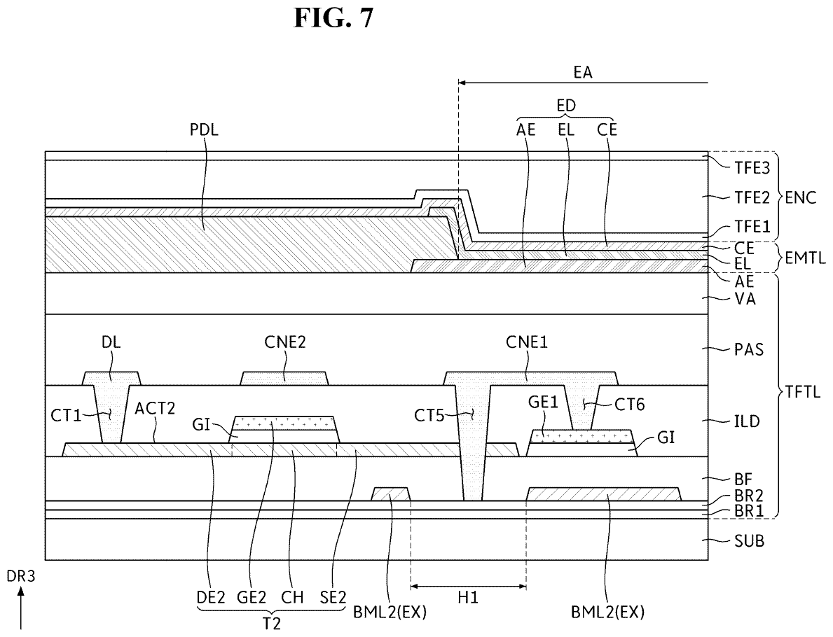

In an embodiment, during the manufacturing of the display device 100, a short circuit between the second light-shielding layer BML2 and the first connection electrode CNE1 may be prevented by the first hole H1 of the second light-shielding layer BML2. This will hereinafter be described with reference to FIG. 7.

FIG. 7 is a schematic diagram for explaining the principle of preventing a short circuit between the second light-shielding layer BML2 and the first connection electrode CNE1 in the display device 100.

In an etching process for forming the fifth contact hole CT5, the second active layer ACT2, which is relatively thin, may be damaged by the etching process. For example, the fifth contact hole CT5 may penetrate not only the interlayer insulating film ILD but also the second active layer ACT2 and the buffer layer BF. The first connection electrode CNE1 in the fifth contact hole CT5 may extend to the second barrier layer BR2. For example, one side of the first connection electrode CNE1 may contact the second barrier layer BR2. However, since the second light-shielding layer BML2 has the first hole H1 in the region overlapping the fifth contact hole CT5, the first connection electrode CNE1, extending to the second barrier layer BR2, may be disposed in the first hole H1 of the second light-shielding layer BML2 and may not contact the second light-shielding layer BML2. In other words, the first connection electrode CNE1 in the fifth contact hole CT5 may be surrounded by the first hole H1 of the second light-shielding layer BML2, remaining spaced apart from the second light-shielding layer BML2. Therefore, even if the second active layer ACT2 is damaged during the formation of the fifth contact hole CT5, a short circuit between the first connection electrode CNE1 and the second light-shielding layer BML2 in the fifth contact hole CT5 can be prevented. In other words, the second light-shielding layer BML2 includes the extension portion EX that overlaps the second active layer ACT2 and the fifth contact hole CT5. Due to the extension portion EX, parasitic capacitance can be minimized, as described above, and a short circuit between the first connection electrode CNE1 and the second light-shielding layer BML2 can be prevented by the first hole H1 of the extension portion EX.

Referring to FIG. 7, the first connection electrode CNE1 in the fifth contact hole CT5 may penetrate the second active layer ACT2. For example, the first connection electrode CNE1 may penetrate the second source electrode SE2 of the second active layer ACT2 in the third direction D3. The first connection electrode CNE1 may contact the inner wall of the penetrated second active layer ACT2.

As illustrated in FIG. 7, the first connection electrode CNE1, which extends through the second active layer ACT2 to the second barrier layer BR2, may be surrounded by the first hole H1 of the second light-shielding layer BML2.

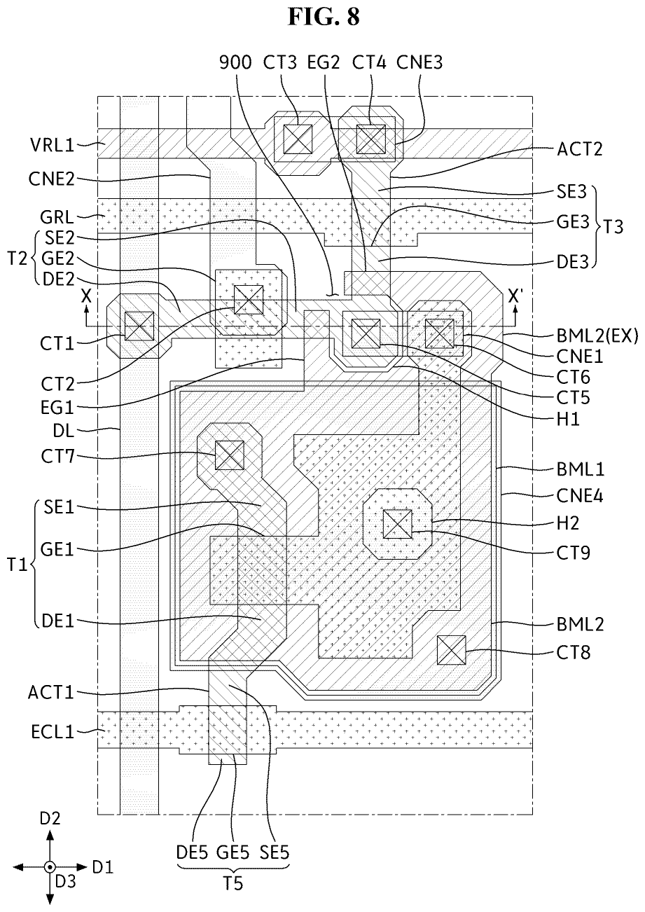

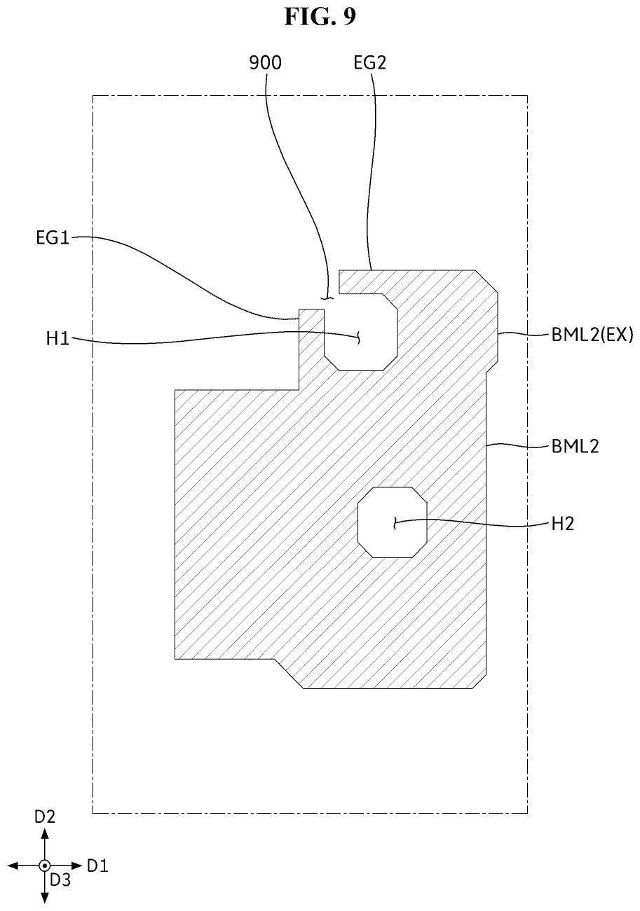

FIG. 8 is a schematic diagram illustrating the array of a display device 100 according to another embodiment of the disclosure, and FIG. 9 is a schematic diagram selectively illustrating only a second light-shielding layer BML2 of FIG. 8.

The display device 100 of FIGS. 8 and 9 differs from the display device 100 of the counterparts of FIGS. 4 and 5 in that it further includes a side opening 900, and will hereinafter be described, focusing mainly on this difference.

Referring to FIGS. 8 and 9, the side of a first hole H1 may be open. For example, the first hole H1 may have a side opening 900 that exposes the side of the first hole H1.

The display device according to the embodiment can be applied to various electronic devices. The electronic device according to one embodiment includes the display device described above and may further include modules or devices having additional functions in addition to the display device.

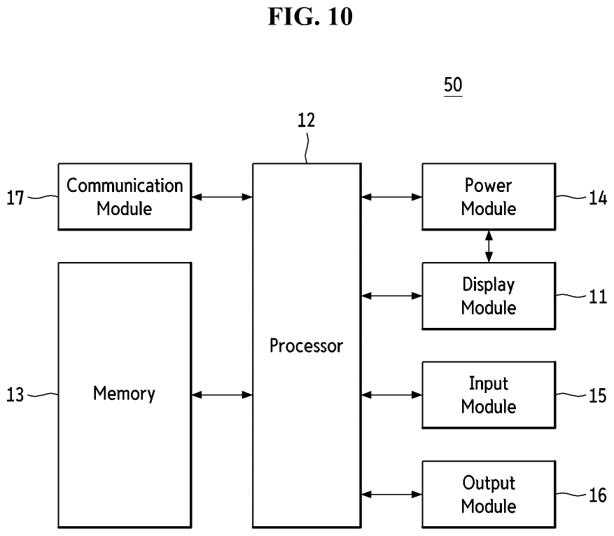

FIG. 10 is a schematic block diagram of an electronic device according to an embodiment. Referring to FIG. 10, the electronic device 50 according to one embodiment may include a display module 11, a processor 12, a memory 13, and a power module 14. The electronic device 50 may further include an input module 15, a non-image output module 16 and/or a communication module 17.

The electronic device 50 may output various information in the form of images through the display module 11. When the processor 12 executes an application stored in the memory 13, image information provided by the application may be provided to the user through the display module 11. The power module 14 may include a power supply module such as a power adapter or a battery device, and a power conversion module that converts the power supplied by the power supply module to generate power required for the operation of the electronic device 5000. The input module 14 may provide input information to the processor 12 and/or the display module 11. The non-image output module 16 may receive information other than images transmitted from the processor 12, such as sound, haptics, and light, and provide the information to the user. The communication module 17 is a module that is responsible for transmitting and receiving information between the electronic device 50 and an external device, and may include a receiving unit and a transmitting unit.

At least one of the components of the electronic device 50 described above may be included in the display device according to the embodiments described above. In addition, some of the individual modules functionally included in one module may be included in the display device, and others may be provided separately from the display device. For example, the display device includes a display module 11, and the processor 12, memory 13, and power module 14 may be provided in the form of other devices within the electronic device 50 other than the display device.

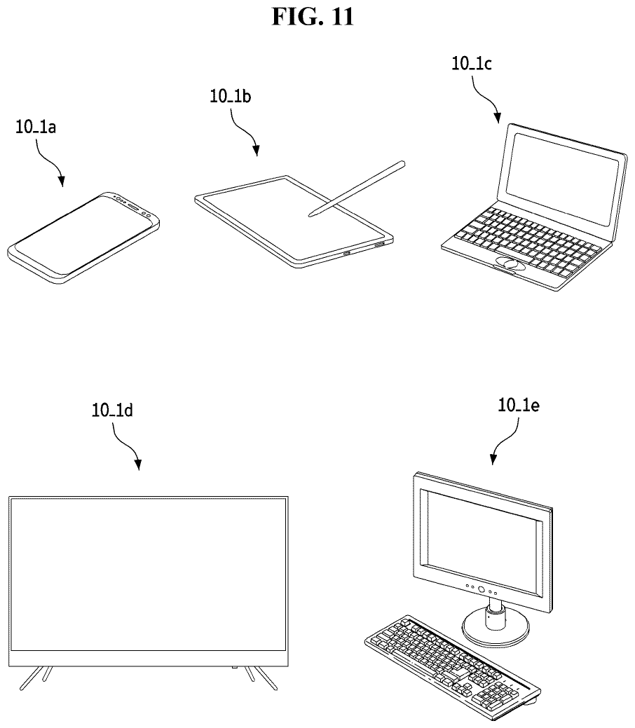

FIGS. 11, 12, and 13 are schematic diagrams of electronic devices according to various embodiments. FIGS. 11 to 13 illustrate examples of various electronic devices to which the display device according to the embodiments is applied.

FIG. 11 illustrates a smartphone 10_1a, a tablet PC 10_1b, a laptop 10_1c, a TV 10_1d, and a desk monitor 10_1e as examples of electronic devices.

In addition to the display module 11, the smartphone 10_1a may include an input module such as a touch sensor and a communication module. The smartphone 10_1a may process information received through the communication module or other input modules and display the information through the display module of the display device.

In the case of tablet PCs 10_1b, laptops 10_1c, TVs 10_1d, and desk monitors 10_1e, they may also include display modules and input modules similar to smartphones 10_1a, and may additionally include communication modules in some cases.

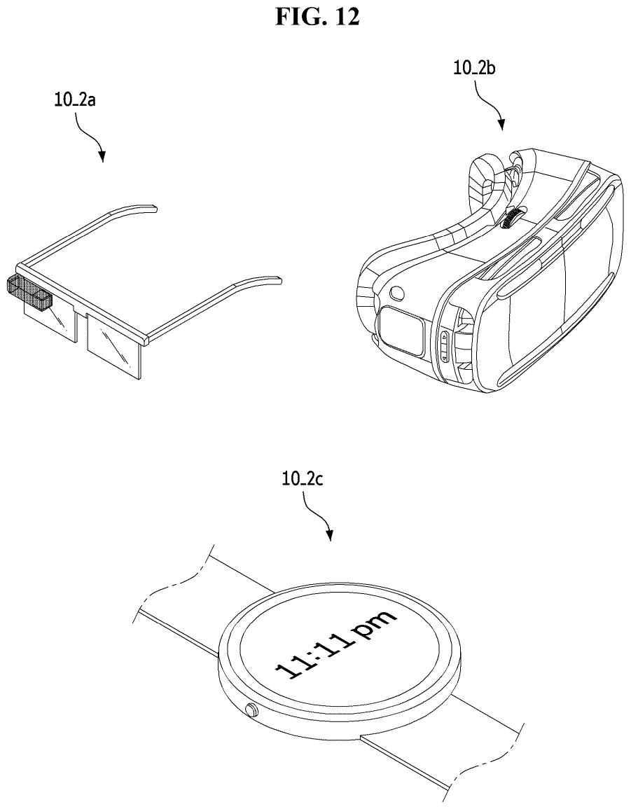

FIG. 12 shows an example of an electronic device including a display module being applied to a wearable electronic device. The wearable electronic device may be a smart glasses 10_2a, a head-mounted display 10_2b, a smart watch 10_2c, etc.

The smart glasses 10_2a and the head-mounted display 10_2b may include a display module that emits a display image and a reflector that reflects the emitted display screen and provides it to the user's eyes, thereby providing a virtual reality or augmented reality screen to the user.

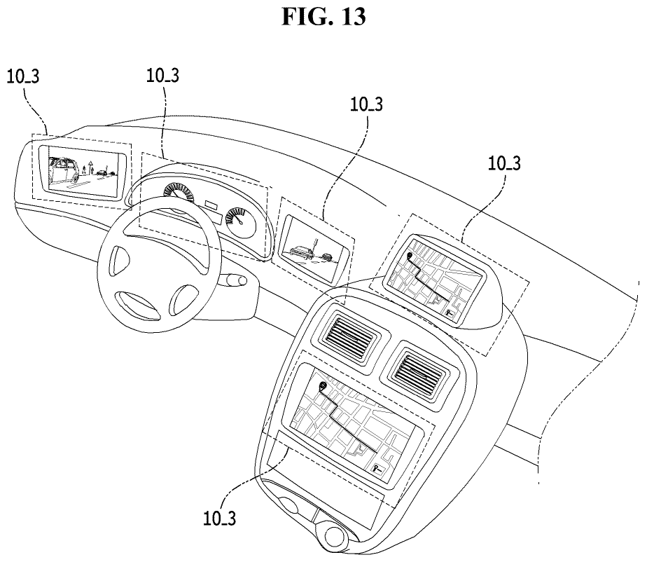

The smart watch 10_2c may include a biometric sensor as an input device and may provide biometric information recognized by the biometric sensor to the user through the display module. FIG. 13 illustrates a case where an electronic device including a display module is applied to a vehicle. For example, the electronic device 10_3 may be applied to a dashboard, center fascia, etc. of a vehicle, or may be applied to a CID (Center Information Display) placed on a dashboard of a vehicle, or a room mirror display replacing a side mirror.

In concluding the detailed description, those skilled in the art will appreciate that many variations and modifications can be made to the preferred embodiments without substantially departing from the principles of the present invention. Therefore, the disclosed preferred embodiments of the invention are used in a generic and descriptive sense only and not for purposes of limitation.

What is claimed is:

1. A display device comprising:
a substrate;
a light-shielding layer disposed on the substrate;
an active layer disposed on the light-shielding layer;
a first transistor including a gate electrode disposed adjacent to the active layer;
a light-emitting element electrically connected to the first transistor; and
a connection electrode disposed on the active layer and the gate electrode, wherein
the connection electrode is connected to the active layer through a first contact hole in an interlayer insulating film and to the gate electrode through a second contact hole in the interlayer insulating film, and
the light-shielding layer does not overlap the first contact hole.

2. The display device of claim 1, wherein
the light-shielding layer has a hole that penetrates the light-shielding layer, and
the hole of the light-shielding layer overlaps the first contact hole.

3. The display device of claim 2, wherein in a plan view, the hole of the light-shielding layer surrounds the first contact hole.

4. The display device of claim 2, wherein the hole of the light-shielding layer overlaps the active layer.

5. The display device of claim 2, wherein the hole of the light-shielding layer is disposed close to edges of the light-shielding layer.

6. The display device of claim 1, wherein the connection electrode in the first contact hole penetrates the active layer.

7. The display device of claim 6, wherein the connection electrode contacts an inner wall of the penetrated active layer.

8. The display device of claim 2, wherein the connection electrode in the first contact hole is surrounded by the hole of the light-shielding layer.

9. The display device of claim 2, wherein a side of the hole in the light-shielding layer is open.

10. The display device of claim 2, further comprising:
a second transistor and a third transistor electrically connected to the gate electrode of the first transistor.

11. The display device of claim 10, wherein
the hole of the light-shielding layer is disposed close to edges of the light-shielding layer, and
in a plan view, the edges of the light-shielding layer include a first edge facing a gate electrode of the second transistor and a second edge facing a gate electrode of the third transistor.

12. A display device comprising:
a substrate;
a light-shielding layer disposed on the substrate;
an active layer disposed on the light-shielding layer;
a first transistor including a gate electrode disposed adjacent to the active layer;
a light-emitting element electrically connected to the first transistor; and
a connection electrode disposed on the active layer and the gate electrode, wherein
the connection electrode is connected to the active layer through a first contact hole in an interlayer insulating film and to the gate electrode through a second contact hole in the interlayer insulating film, and
the light-shielding layer has a hole that overlaps the first contact hole.

13. The display device of claim 12, wherein in a plan view, the hole of the light-shielding layer surrounds the first contact hole.

14. The display device of claim 12, wherein the hole of the light-shielding layer overlaps the active layer.

15. The display device of claim 12, wherein the hole of the light-shielding layer is disposed close to edges of the light-shielding layer.

16. The display device of claim 12, wherein the connection electrode in the first contact hole penetrates the active layer.

17. The display device of claim 16, wherein the connection electrode contacts an inner wall of the penetrated active layer.

18. The display device of claim 12, wherein the connection electrode in the first contact hole is surrounded by the hole of the light-shielding layer.

19. The display device of claim 12, wherein a side of the hole in the light-shielding layer is open.

20. The display device of claim 12, further comprising:
a second transistor and a third transistor electrically connected to the gate electrode of the first transistor.

21. The display device of claim 20, wherein
the hole of the light-shielding layer is disposed close to edges of the light-shielding layer, and
in a plan view, the edges of the light-shielding layer include a first edge facing a gate electrode of the second transistor and a second edge facing a gate electrode of the third transistor.

22. An electronic device comprising:
a display device including a screen; wherein
the display device includes:
a substrate;
a light-shielding layer disposed on the substrate;
an active layer disposed on the light-shielding layer;
a first transistor including a gate electrode disposed adjacent to the active layer;
a light-emitting element electrically connected to the first transistor; and
a connection electrode disposed on the active layer and the gate electrode,
the connection electrode is connected to the active layer through a first contact hole in an interlayer insulating film and to the gate electrode through a second contact hole in the interlayer insulating film, and
the light-shielding layer does not overlap the first contact hole.
